(19) United States
(12) Patent Application Publication
(10) Pub. No.: US 2022/0377948 A1
(43) Pub. Date: Nov. 24, 2022

(54) POWER CONVERTER

(71) Applicant: DENSO CORPORATION, Kariya-city (JP)

(72) Inventors: Mamoru KUWAHARA, Kariya-city (JP); Yuuta HASHIMOTO, Kariya-city (JP); Kazuya TAKEUCHI, Kariya-city (JP)

(73) Assignee: DENSO CORPORATION, Kariya-city (JP)

(21) Appl. No.: 17/879,570

(22) Filed: Aug. 2, 2022

Related U.S. Application Data
(63) Continuation of application No. PCT/JP2020/048187, filed on Dec. 23, 2020.

(30) Foreign Application Priority Data
Feb. 5, 2020 (JP) 2020-018236

(51) Int. Cl. H05K 7/20

(52) U.S. Cl. CPC H05K 7/20927

(57) ABSTRACT

A power converter includes a heat generator configured to generate heat through power conversion, and a case housing the heat generator. The case includes a case member that is made of resin and defines an opening, and a cooler that is made of metal and disposed to cover the opening. The cooler includes a cooling water passage for cooling the heat generator. The case member includes an upper case member that defines an upper opening to be covered by a cover member, and a lower case member that defines the opening covered by the cooler. One of the upper case member and the lower case member has an input side attachment portion to be attached to an input terminal and the other of the upper case member and the lower case member has an output side attachment portion to be attached to an output terminal.

### CROSS REFERENCE TO RELATED APPLICATIONS

The present application is a continuation application of International Patent Application No. PCT/JP2020/048187 filed on Dec. 23, 2020, which designated the U.S. and claims the benefit of priority from Japanese Patent Application No. 2020-018236 filed on Feb. 5, 2020. The entire disclosures of all of the above applications are incorporated herein by reference.

### TECHNICAL FIELD

The present disclosure relates to a power converter.

### BACKGROUND

A power converter having a resin case for housing a power semiconductor module and a metal case for housing a control circuit board has been known. The resin case includes a refrigerant passage through which a refrigerant for cooling the power semiconductor module flows.

### SUMMARY

A power converter includes a heat generator configured to generate heat through power conversion and a case housing the heat generator. The case includes a case member that is made of resin and defines an opening, and a cooler that is made of metal and disposed to cover the opening. The cooler includes a cooling water passage for cooling the heat generator. The case member includes an upper case member that defines an upper opening to be covered by a cover member, and a lower case member that defines the opening covered by the cooler. One of the upper case member and the lower case member has an input side attachment portion to be attached to an input terminal and the other of the upper case member and the lower case member has an output side attachment portion to be attached to an output terminal.

### BRIEF DESCRIPTION OF DRAWINGS

FIG. 1 is a perspective view illustrating a power converter.

FIG. 2 is a perspective view illustrating a case member.

FIG. 3 is a perspective view illustrating a cooler.

FIG. 4 is a perspective view illustrating a case.

FIG. 5 is a top view of the case with an upper case member removed.

FIG. 6 is a cross-sectional view taken along a line VI-VI of FIG. 5.

FIG. 7 is a cross-sectional view of a case according to a second embodiment.

### DESCRIPTION OF EMBODIMENTS

To begin with, examples of relevant techniques will be explained.

A power converter having a resin case for housing a power semiconductor module and a metal case for housing a control circuit board has been known. The resin case includes a refrigerant passage through which a refrigerant for cooling the power semiconductor module flows.

Housing of the power converter is made of two materials, that are a metal material and a resin material which is lighter than the metal material. Thereby, the weight of the power converter is reduced. However, in a configuration where a case defines one of a plurality of housing space and the entire of the inside of the case is used as a cooling passage, it is required to dispose a structure that covers cooling target elements for separating the cooling target elements from the cooling water. The structure may be realized by using an exterior case for each of the cooling target elements disposed in the cooling water passage. Thus, the size of the entire housing including the structure that separates the cooling target elements from the cooling water is large, and the weight of the housing tends to be heavy. From the viewpoint described above or from other unmentioned viewpoints, there is demand for further improvement to the power converter.

It is an objective of the present disclosure to provide a lightweight power converter.

The power converter disclosed herein includes a heat generator configured to generate heat through power conversion and a case housing the heat generator. The case includes a case member that is made of resin and defines an opening, and a cooler that is made of metal and disposed to cover the opening. The cooler includes a cooling water passage for cooling the heat generator.

The power converter disclosed herein includes a metal cooler that is disposed to cover the opening of the case and has a cooling passage for cooling a heat generator. Therefore, it is not necessary to provide a structure that covers the heat generator that is a cooling target for separating the heat generator from the cooling water. Therefore, the size of the case can be decreased and the weight can be lightened. Therefore, a lightweight power converter can be provided.

Hereinafter, a plurality of embodiments will be described with reference to the drawings. In some embodiments, functionally and/or structurally corresponding and/or associated parts may be given the same reference numerals, or reference numerals with different digit placed on equal to or higher than a hundred place. For corresponding parts and/or associated parts, additional explanations can be made to the description of other embodiments.

### First Embodiment

A power converter 1 is a device that converts power supply voltage into a desired voltage and frequency. By converting the electric power to a desired value by the power converter 1, it is possible to appropriately drive an electric load. The power converter 1 can be used as an inverter that converts direct current into alternating current, for example. The power converter 1 can be used as a converter that converts alternating current into direct current, for example. The power converter 1 can be used as a device that supplies electric power to drive a motor mounted in and used in an airplane, for example. However, the power converter 1 may be mounted in a vehicle such as an automobile and a train.

The power converter 1 includes various units such as a semiconductor unit and a capacitor unit. The semiconductor unit includes switching elements such as MOSFETs and IGBTs. The semiconductor unit can convert direct current into alternating current by controlling timing of current flow.

The capacitor unit includes a plurality of capacitor elements. The capacitor element is, for example, a smoothing capacitor element for smoothing a voltage. The capacitor element is, for example, a noise removing capacitor element for guiding noise to the ground.

The power converter 1 includes a control board that controls current flowing through various units. The power converter 1 includes a bus bar that provides a current passage. The power converter 1 includes a current sensor that measures the magnitude of the current flowing through the bus bar or the like. The entire or a part of each of the control board, the current sensor, and the bus bar is made of metal.

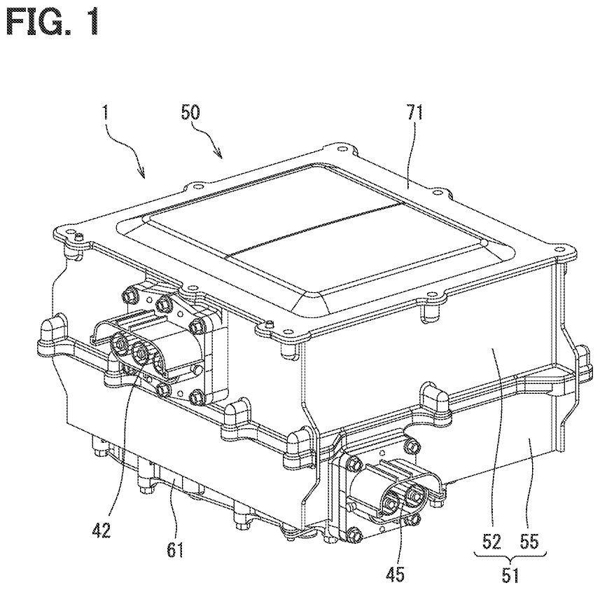

In FIG. 1, the power converter 1 includes a case 50 and a cover member 71. The case 50 has a box shape having an opening at an upper portion of the case 50. The cover member 71 is a member for closing the upper opening of the case 50 after various units are stored in the case 50. The cover member 71 is made of a resin material, which is a lighter material than metal. When the cover member 71 is attached to the case 50, the case 50 is in the closed state that liquid is prevented from entering into the case 50. By attaching the cover member 71 to the case 50, housing of the power converter 1 is configured.

The case 50 includes a case member 51 and a cooler 61. The case member 51 includes two members that are an upper case member 52 and a lower case member 55. The upper case member 52 is made of a resin material, which is lighter than metal. The cover member 71 is attached to the upper case member 52. An output connector 42 protrudes from the side surface of the upper case member 52. To the output connector 42, an electric load to which converted electric power is supplied is connected. The electrical load is, for example, a motor device.

The lower case member 55 is made of a resin material, which is lighter than metal, like the upper case member 52. The cooler 61 is attached to the lower case member 55. The cooler 61 and the cover member 71 face each other in the up-down direction. An input connector 45 protrudes from the side surface of the lower case member 55. To the input connector 45, an external power source that supplies electric power to the power converter 1 is connected.

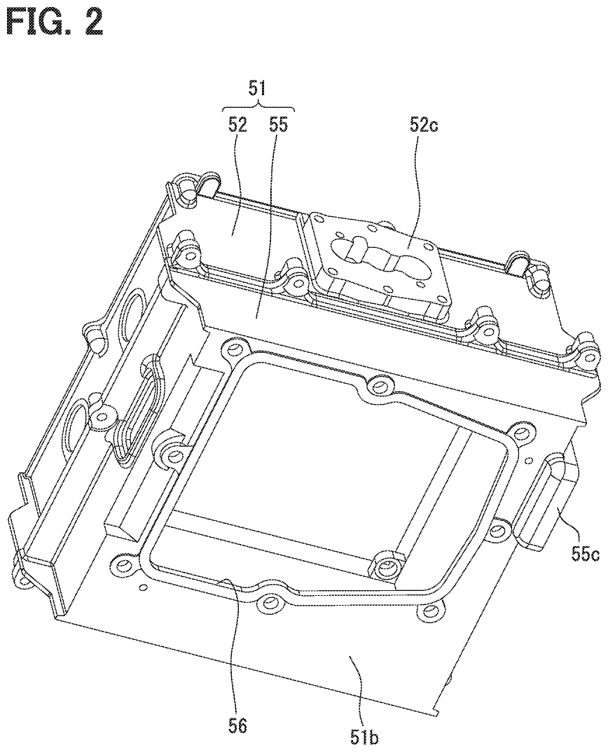

As shown in FIG. 2, the upper case member 52 includes an output side attachment portion 52c for receiving the output connector 42. The output side attachment portion 52c defines a communication hole that fluidly connects between the inside and the outside of the upper case member 52. The lower case member 55 includes an input side attachment portion 55c for receiving the input connector 45. The input side attachment portion 55c defines a communication hole that fluidly connects between the inside and the outside of the lower case member 55. The output side attachment portion 52c and the input side attachment portion 55c are provided respectively on different surfaces of the four side surfaces of the case member 51.

The bottom surface of the lower case member 55 forms a case bottom surface 51b, which is the bottom surface of the case member 51. The case bottom surface 51b defines a bottom opening 56 to which the cooler 61 is attached. The bottom opening 56 has a substantially trapezoidal shape. The length of the side of the bottom opening 56 is shortest at the side close to the side surface having the input side attachment portion 55c. The bottom opening 56 provides an example of an opening.

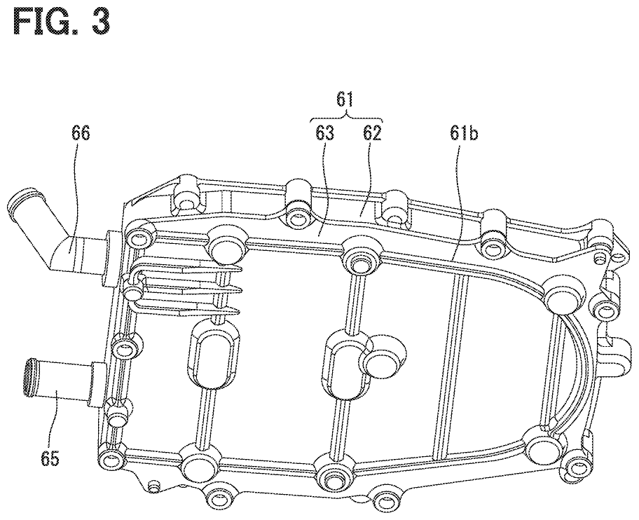

As shown in FIG. 3, the cooler 61 includes a cooler body 62 and a cooler cover 63. The cooler cover 63 forms a cooler bottom surface 61b, which is the bottom surface of the cooler 61. The cooler 61 defines a cooling water passage thereien. The entire of the cooler 61 including the cooler body 62 and the cooler cover 63 is made of a metal material having high thermal conductivity. The metal material forming the cooler 61 is, for example, aluminum.

The cooler 61 includes an inlet pipe 65 for introducing a cooling water into the cooling water passage in the cooler 61. The cooler 61 includes an outlet pipe 66 for draining the cooling water from the cooling water passage in the cooler 61. The outlet pipe 66 includes a bent portion that is bent upward.

The inlet pipe 65 and the outlet pipe 66 are provided on the same surface of the cooler 61. The cooling water passage extends to the side of the cooler 61 opposite to the inlet pipe 65, is U-turned, and is fluidly connected to the outlet pipe 66. Thus, the cooling water can be distributed throughout the cooler 61.

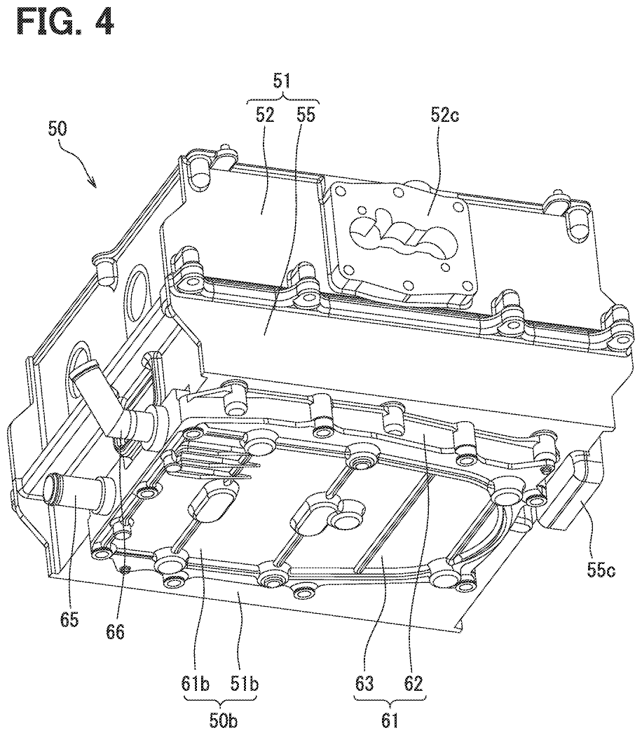

As shown in FIG. 4, the upper case member 52 and the lower case member 55 are fastened and fixed to each other by fastening members to form the case member 51. The cooler 61 and the case member 51 are fixed with each other by fastening members to form the case 50. The fastening member is, for example, a screw member. However, the fixing method is not limited to fastening and fixing. For example, they may be fixed with each other with an adhesive. A sealing member such as a liquid gasket or an O-ring is interposed between the case member 51 and the cooler 61. This prevents a gap from being defined between the case member 51 and the cooler 61.

The cooler 61 is not housed inside the case member 51. The cooler 61 is attached to the case member 51 to extend outward more than the case member 51 does. The cooler 61 is attached to the case member 51 to cover the bottom opening 56 of the case member 51 from the outside of the bottom opening 56. Therefore, after the cooler 61 is attached to the case member 51, the bottom opening 56 cannot be visually recognized from the outside.

The inlet pipe 65 and the outlet pipe 66 are located on a surface of the case 50 facing different from the surfaces having the output side attachment portion 52c and the input side attachment portion 55c. Specifically, the inlet pipe 65 and the outlet pipe 66 are located on the surface of the four side surfaces forming the case 50 opposite to the surface having the input side attachment portion 55c.

The bottom surface portion 50b, which is the bottom surface of the case 50, is formed of two bottom surfaces that are the case bottom surface 51b and the cooler bottom surface 61b. In other words, the bottom surface portion 50b has two types of portions made of different materials that are a metal portion having a high cooling performance and a resin portion having a low cooling performance. Further, the cooler 61 is exposed to the outside of the case 50.

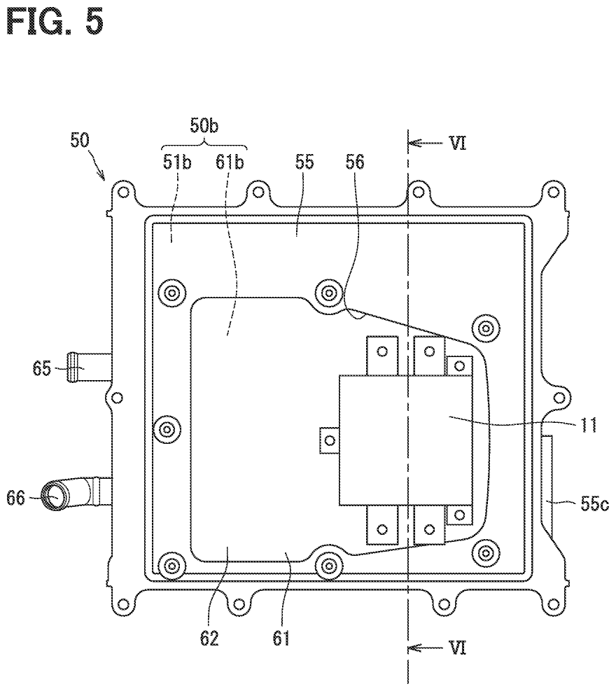

In FIG. 5, a reactor unit 11 is provided inside the case 50. The reactor unit 11 includes a reactor element. The reactor element is, for example, an element for boosting a voltage. The reactor element is, for example, a choke coil. The reactor unit 11 is a heat generator that generates heat when electric current flows through the heat generator during power conversion. The reactor unit 11 is mounted directly on the cooler 61. Therefore, the reactor unit 11 is cooled from the contact portion with the cooler 61. The reactor unit 11 provides an example of a heat generator.

The area of the cooler bottom surface 61b is larger than the area of the case bottom surface 51b. In other words, the ratio of the area occupied by the cooler bottom surface 61b in the bottom surface portion 50b is 50% or more. In the rectangular bottom surface portion 50b, the cooler bottom surface 61b, not the case bottom surface 51b, is located in the central portion of the bottom surface portion 50b.

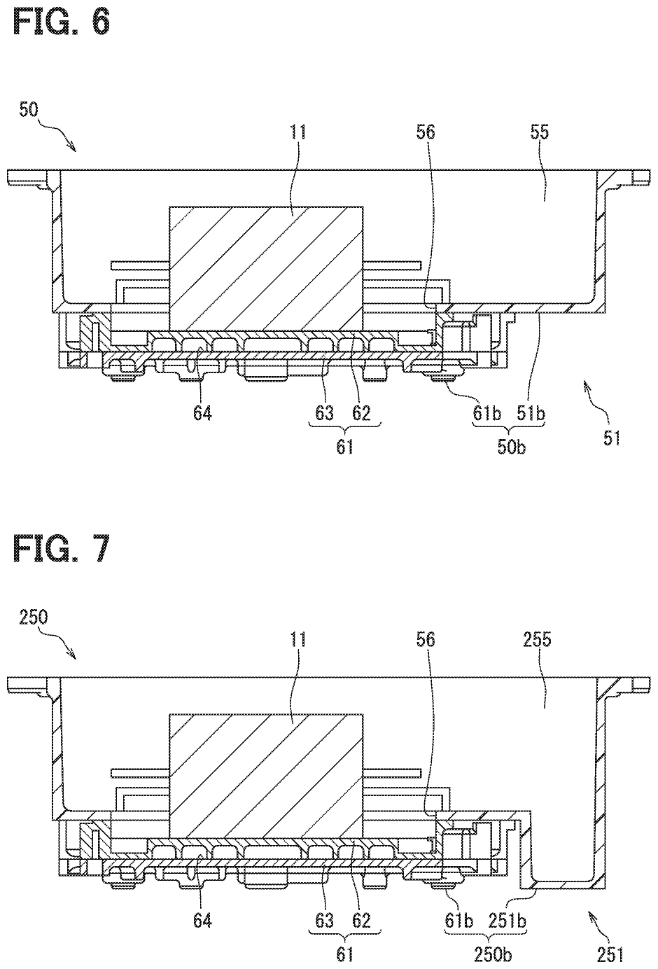

As shown in FIG. 6, a plurality of cooling water passages 64 that serve as a cooling water passage are defined inside the cooler 61. The cooling water passages 64 are arranged side by side without intersecting each other. The reactor unit 11 is located at a position facing the plurality of cooling water passages 64 in the up-down direction. Therefore, the reactor unit 11 is cooled by the cooling water flowing through the plurality of cooling water passages 64. The reactor unit 11 is in contact with the outer surface of the portion of the cooler body 62 whose inner surface defines the cooling water passages 64. In other words, the cooler 61 is arranged around the reactor unit 11. The cooling water flows through the cooling water passages 64 without directly contacting the reactor unit 11.

Since the cooler 61 is made of a metal having high thermal conductivity, the heat of the reactor unit 11 is conducted to the cooling water passages 64.

The cooling water flowing from the inlet pipe 65 flows into the cooling water passages 64 and cools the reactor unit 11. After that, the cooling water whose temperature has increased flows out of the cooler 61 through the outlet pipe 66. As described above, the reactor unit 11 is kept being cooled by introducing the cooling water whose temperature has not increased yet into the cooling water passages 64 and discharging the cooling water whose temperature has increased out of the cooling water passages 64.

The cooler bottom surface 61b protrudes downward more than the case bottom surface 51b does. In other words, the lower case member 55 does not have a portion that faces the side surface of the cooler 61 in the horizontal direction, which is a direction perpendicular to the up-down direction. Therefore, air can freely flow along each of the side surfaces of the cooler 61.

According to the above-described embodiment, the power converter 1 includes the metal cooler 61 disposed to cover the bottom opening 56 and including the cooling water passages 64 for cooling the reactor unit 11. Therefore, by arranging the cooler 61 around the heat generator such as the reactor unit 11, the heat generator can be cooled without providing a structure to cover the heat generator for separating the heat generator from the cooling water. Therefore, the size and the weight of the case 50 for housing the heat generator can be reduced. Further, the case 50 can be formed of the case member 51 made of resin and the cooler 61 made of metal and having a cooling function. Therefore, the metal cooler 61 can exert two functions, that is, a cooling function for cooling the heat generator and a part of the storage function for storing the heat generator. As a result, the weight of the case 50 can be easily reduced as compared with the case where the case 50 is made of only metal. Alternatively, the weight of the case 50 can be easily reduced as compared with the case where the case 50 is made of only resin and a metal device exhibiting a cooling function is stored inside. As described above, the lightweight power converter 1 can be provided.

On the outside of the case 50, the cooler 61 extends outward more than the case member 51 does. Thus, it is possible to prevent the cooler 61 from being surrounded by the case member 51. Therefore, it is easy for air to flow around the cooler 61. Therefore, the cooling effect of the cooler 61 can be spread to the outside of the case 50. Alternatively, when the temperature of the cooler 61 is increased by cooling the reactor unit 11, it is easy to cool the cooler 61 by the ambient air.

The cooler 61 forms at least a part of the bottom surface of the case 50. Therefore, the cooler 61, which is made of a metal material heavier than the resin material, can be positioned at a lower position. Therefore, it is easy to set the gravity center of the power converter 1 to a low position. In particular, when the power converter 1 is mounted in a moving body such as an airplane or a vehicle, an external force such as vibration is likely to be applied to the power converter 1. Therefore, a configuration in which the gravity center of the power converter 1 is lowered and the appropriate position of the power converter 1 is stably kept is very important when the power converter 1 is mounted in the moving body.

The bottom surface portion 50b includes a resin case bottom surface 51b and a metal cooler bottom surface 61b. Therefore, only the part that requires the cooling function can be made of metal, and the part that does not need the cooling function can be made of resin. Therefore, as compared with the case where the entire of the bottom surface portion 50b is made of metal, it is easy to reduce the weight of the case 50 while providing the required cooling function.

The cooler bottom surface 61b has an area larger than the area of the case bottom surface 51b. Therefore, in the bottom surface portion 50b, a large area can be secured for the cooling function. Therefore, it is easy to improve the cooling performance for cooling the heat generator.

The cooler bottom surface 61b is provided at a position of the bottom surface portion 50b to include the central portion. Therefore, it is possible to prevent the gravity center of the power converter 1 from being extremely offset from the center position of the bottom surface portion 50b in the horizontal direction. Therefore, by setting the gravity center of the power converter 1 to a position close to the center position, it is possible to stably maintain an appropriate position of the power converter 1. This configuration is particularly important when the power converter 1 is mounted in a moving body to which an external force such as vibration is likely to be applied. In the power converter 1, the cooler 61 takes part in cooling the heat generator. Therefore, by adjusting the size and position of the cooler 61 according to the size and position of the heat generator that is a cooling target, the heat generator can be appropriately cooled. Therefore, it is easy to downsize the cooler 61 according to the size of the heat generator.

### Second Embodiment

This embodiment is a modification based on the preceding embodiment. In this embodiment, the cooler bottom surface 61b and the case bottom surface 251b that face outward are flush with each other.

As shown in FIG. 7, a part of the lower case member 255 forming a part of the case member 251 protrudes downward. In other words, the lower case member 255 includes an attachment recess for arranging the cooler 61.

The bottom surface portion 250b, which is the bottom surface of the case 250, is formed of two bottom surfaces that are the case bottom surface 251b, which is the bottom surface of the case member 251, and the cooler bottom surface 61b. In other words, the bottom surface portion 250b has two types of portions made of different materials that are a metal portion having a high cooling performance and a resin portion having a low cooling performance.

In the bottom surface portion 250b, the case bottom surface 251b and the cooler bottom surface 61b are substantially flush with each other. The outer surface of the cooler bottom surface 61b includes an uneven shape which is a step smaller than the step between the attachment recess in the lower case member 255 and the case bottom surface 251b. In other words, the cooler bottom surface 61b is formed of an uneven surface. On the other hand, the case bottom surface 251b is formed of a flat surface. The flat surface of the case bottom surface 251b is located at a height between the concave portion and the convex portion of the uneven surface of the cooler bottom surface 61b.

According to the above-described embodiment, the cooler 61 is provided flush with the case member 251 on the outside of the case 250. Therefore, in the bottom surface portion 250b of the case 250, it is possible to prevent a large step from being defined by the cooler bottom surface 61b and the case bottom surface 251b. Therefore, it is possible to reduce the dead space generated on the outside of the power converter 1 due to the step between the cooler bottom surface 61b and the case bottom surface 251b.

### Other Embodiments

Although an example where the cooler 61 cools the reactor unit 11 has been described, the cooling target of the cooler 61 is not limited to the reactor unit 11. For example, a semiconductor unit or a capacitor unit may be a cooling target. In this case, the semiconductor unit and the capacitor unit provide examples of heat generator. Further, the cooling target of the cooler 61 is not limited to a single element. In other words, the cooler 61 may cool a plurality of heat generators at the same time.

The disclosure in this specification and drawings etc. is not limited to the exemplified embodiment. The disclosure encompasses the illustrated embodiments and variations thereof by those skilled in the art. For example, the present disclosure is not limited to the combinations of components and/or elements shown in the embodiments. The present disclosure may be implemented in various combinations. The present disclosure may have additional members which may be added to the embodiments. The disclosure encompasses omission of components and/or elements of the embodiments. The disclosure encompasses the replacement or combination of components and/or elements between one embodiment and another. The disclosed technical scope is not limited to the description of the embodiments. It should be understood that some disclosed technical ranges are indicated by description of claims, and includes every modification within the equivalent meaning and the scope of description of claims.

The disclosure in the specification, drawings and the like is not limited by the description of the claims. The disclosures in the specification, the drawings, and the like encompass the technical ideas described in the claims, and further extend to a wider variety of technical ideas than those in the claims. Therefore, various technical ideas can be extracted from the disclosure of the specification, the drawings and the like without being limited to the description of the claims.

What is claimed is:

1. A power converter comprising:
a heat generator configured to generate heat through power conversion; and
a case housing the heat generator, wherein
the case includes:
a case member that is made of resin and defines an opening; and
a cooler that is made of metal and disposed to cover the opening, the cooler including a cooling water passage for cooling the heat generator,
the case member includes:
an upper case member that defines an upper opening to be covered by a cover member; and
a lower case member that defines the opening covered by the cooler from an outside of the lower case member, and
one of the upper case member and the lower case member has an input side attachment portion to be attached to an input terminal and the other of the upper case member and the lower case member has an output side attachment portion to be attached to an output terminal.

2. The power converter according to claim 1, wherein
the cooler has at least a part located outside the case member.

3. The power converter according to claim 1, wherein
a surface of the cooler and a surface of the case member that face outward of the case are flush with each other.

4. The power converter according to claim 1, wherein
the cooler forms at least a part of a bottom surface of the case.

5. The power converter according to claim 4, wherein
the case has a bottom surface portion, and
the bottom surface portion includes:
a case bottom surface that is a bottom surface of the case member and made of the resin; and
a cooler bottom surface that is a bottom surface of the cooler and made of the metal.

6. The power converter according to claim 5, wherein
the cooler bottom surface has an area larger than that of the case bottom surface.

7.The power converter according to claim 5, wherein
the cooler bottom surface is positioned to include a center portion of the bottom surface portion of the case.
